(19) United States
(12) Patent Application Publication
(10) Pub. No.: US 2024/0395676 A1
(43) Pub. Date: Nov. 28, 2024

(54) Package with Single Integral Body Carrying Two Transistor Chips with Half Bridge Configuration

(71) Applicant: Infineon Technologies AG, Neubiberg (DE)

(72) Inventors: Marcus Böhm, Mintraching (DE); Bernd Richard Schmölzer, Radenthein (AT); Lisa Marie Holzmann, München (DE); Thorsten Scharf, Lappersdorf, Kareth (DE)

(21) Appl. No.: 18/670,000

(22) Filed: May 21, 2024

(30) Foreign Application Priority Data
May 22, 2023 (DE) 102023113278.4

(51) Int. Cl. H01L 23/495; H01L 23/00; H01L 23/31

(52) U.S. Cl. CPC H01L 23/49562; H01L 23/3107; H01L 23/49568; H01L 23/49575; H01L 24/40; H01L 24/48; H01L 24/73; H01L 2224/40175; H01L 2224/48175; H01L 2224/73221

(57) ABSTRACT

A package includes a single integral electrically conductive body, a first chip with an integrated transistor and including a first terminal, a second terminal, and a third terminal, wherein the second terminal and the third terminal are formed on one main surface of the first chip and the first terminal is formed on an opposing main surface of the first chip, and a second chip with an integrated transistor and comprising a fourth, fifth and sixth terminals, wherein the fourth terminal and the sixth terminal are formed on one main surface of the second chip and the fifth terminal is formed on another surface of the second chip, wherein the first chip and the second chip are connected to form a half bridge.

### FIELD OF THE INVENTION

The present invention relates to a package and to a method of manufacturing a package.

### BACKGROUND

A package, for instance for automotive applications, provides a physical containment for one or more electronic chips comprising one or more integrated circuit elements. Examples of integrated circuit elements of packages are a metal oxide semiconductor field effect transistor (MOSFET), an insulated-gate bipolar transistor (IGBT), and a diode.

There is still potentially room to improve electric performance and thermal reliability of a package. There may be a need for a package with high electrical performance and thermal reliability.

### SUMMARY OF THE INVENTION

According to an exemplary embodiment, a package is provided which comprises a single integral electrically conductive body, a first chip with an integrated transistor and comprising a first terminal attached on the body, a second terminal, and a third terminal, wherein the second terminal and the third terminal are formed on one main surface of the first chip and the first terminal is formed on an opposing other main surface of the first chip, wherein the first terminal is a drain or collector terminal, the second terminal is a source or emitter terminal, and the third terminal is a gate or base terminal, and a second chip with an integrated transistor and comprising a fourth terminal attached on the body, a fifth terminal and a sixth terminal, wherein the fourth terminal and the sixth terminal are formed on one main surface of the second chip and the fifth terminal is formed on an opposing other main surface of the second chip, wherein the fourth terminal is a source or emitter terminal, the fifth terminal is a drain or collector terminal, and the sixth terminal is a gate or base terminal, wherein the first chip and the second chip are connected to form a half bridge.

According to another exemplary embodiment, a method of manufacturing a package is provided, wherein the method comprises mounting a first chip, which has an integrated transistor comprising a first terminal, a second terminal and a third terminal, on a single integral electrically conductive body so that the first terminal is attached on the body, wherein the second terminal and the third terminal are formed on one main surface of the first chip and the first terminal is formed on an opposing other main surface of the first chip, mounting a second chip, which has an integrated transistor comprising a fourth terminal, a fifth terminal and a sixth terminal, on the body so that the fourth terminal is attached on the body, wherein the fourth terminal and the sixth terminal are formed on one main surface of the second chip and the fifth terminal is formed on an opposing other main surface of the second chip, wherein the fourth terminal is a source or emitter terminal, the fifth terminal is a drain or collector terminal, and the sixth terminal is a gate or base terminal, and connecting the first chip and the second chip to form a half bridge.

According to an exemplary embodiment, a package comprising two transistor chips connected in half bridge configuration is provided, wherein both transistor chips are assembled on a single integral electrically conductive body (such as a common chip carrier or a common clip). More specifically, a first transistor chip has its drain or collector terminal attached on said body, whereas a second transistor chip has its source or emitter terminal attached on the body. For both transistor chips, the respective drain or connector terminal is formed on one main surface, whereas the respective source or emitter terminal and the respective gate or base terminal are formed on an opposing other main surface. This may allow to operate the transistor chips with vertical current flow which may lead to a compact design and low losses. Descriptively speaking, one die or chip may be in a drain-down arrangement and another die or chip may be in a source-down arrangement, so that they can be attached to a unified body (such as a unified die pad or a unified clip). Advantageously, such an arrangement provides an integrated half bridge functionality featuring a short commutation loop. This may lead to an improved stray inductance, and thus to a reduction of inductive losses. Furthermore, a large die pad area may be obtained in some embodiments. As a result, a high freedom of design may enhance the customizability of the package to specific application requirements. Specifically, this may allow the tailoring of the package thermal reliability-and electrical performance requirements through the enhanced variability of chip placement options on the die pad(s).

### BRIEF DESCRIPTION OF THE DRAWINGS

The accompanying drawings, which are included to provide a further understanding of exemplary embodiments and constitute a part of the specification, illustrate exemplary embodiments. In the drawings:

FIG. 1 shows a schematic circuit diagram of a package with its interconnections according to an exemplary embodiment.

FIG. 2 shows a three-dimensional transparent view of a package according to an exemplary embodiment.

FIG. 3 shows a three-dimensional view of an outline of the package according to FIG. 2.

FIG. 4 shows a circuit diagram of the package according to FIG. 2.

FIG. 5 shows a cross-sectional view of the package according to FIG. 2 with heat sink thereon.

FIG. 6 shows another three-dimensional transparent view of the package according to FIG. 2.

FIG. 7 shows another three-dimensional outline view of the package according to FIG. 2.

FIG. 8 shows a schematic circuit diagram of a package with its interconnections according to another exemplary embodiment.

FIG. 9 shows a three-dimensional transparent view of a package according to an exemplary embodiment according to FIG. 8.

FIG. 10 shows another three-dimensional transparent view of the package according to FIG. 9.

### DETAILED DESCRIPTION OF THE DRAWINGS

The illustrations in the drawing are schematic representations.

In the following, further exemplary embodiments of the package and the method will be explained.

In the context of the present application, the term “package” may particularly denote a device which may comprise at least two chips mounted on a (in particular partially or entirely electrically conductive) carrier. Said constituents of the package may be optionally encapsulated at least partially by an encapsulant. Further optionally, one or more electrically conductive connection elements (such as metallic pillars, bumps, bond wires and/or clips) may be implemented in a package, for instance for electrically coupling and/or mechanically supporting the chips.

In the context of the present application, the term “body” may particularly denote a support structure (which may be at least partially electrically conductive) which serves as a mechanical support for the electronic chips to be mounted thereon or connected therewith, and which may also contribute to the electric interconnection between the electronic chips and the periphery of the package. In other words, the carrier may fulfil a mechanical support function and optionally an electric connection function. For example, such a body may be a carrier or a clip. When the carrier forms part of a leadframe, it may be or may comprise a die pad. For instance, such a carrier may be a leadframe structure (for instance made of copper), a DAB (Direct Aluminum Bonding) substrate, a DCB (Direct Copper Bonding) substrate, etc. Moreover, the carrier may also be configured as Active Metal Brazing (AMB) substrate.

In the context of the present application, the term “single integral electrically conductive body” may particularly denote a carrier or clip or other kind of body realized as only one continuous body and being at least partially electrically conductive.

In the context of the present application, the term “chip” may in particular denote a semiconductor chip (in particular a power semiconductor chip). The chip may be an active electronic device. In particular, the chip may be a semiconductor chip having at least one integrated circuit element (such as a transistor) in a surface portion thereof. The chip may be a bare die or may be already packaged or encapsulated. Semiconductor chips implemented according to exemplary embodiments may be formed for example in silicon technology, gallium nitride technology, silicon carbide technology, etc.

In the context of the present application, the term “chip with integrated transistor” may in particular denote a chip, such as a semiconductor chip, in which at least a transistor may be integrated, in particular monolithically integrated. Optionally, the chip may comprise at least one further integrated circuit element, such as a diode or a further transistor. In particular, a respective chip with integrated transistor may be a field-effect transistor chip having a source terminal, a drain terminal and a gate terminal. Alternatively, a respective chip with integrated transistor may be a bipolar transistor chip having an emitter terminal, a collector terminal and a base terminal. Specific examples of the transistor chips are a metal oxide semiconductor field effect transistor (MOSFET), and an insulated-gate bipolar transistor (IGBT).

In the context of the present application, the term “half bridge” may particularly denote a circuit composed of an upper transistor switch (“high-side”) and a lower transistor switch (“low-side”). For instance, the transistors may be MOSFETs, i.e. metal oxide semiconductor field effect transistors. The transistors may be connected in a cascode arrangement. The two transistor switches may be turned on and off complementary to each other (in particular with a non-overlapping dead-time) by applying corresponding voltage waveforms at the control terminals. A desired result may be an idealized DC-DC conversion scenario, where a square-wave mid voltage level switches between a first electric potential (such as a DC (direct current) bus voltage) and a second electric potential (such as ground). However, other shapes of an output signal may be possible which do not have a square-wave characteristic. The two transistors may be interconnected with a mutual connection of their connection terminals so that a two-transistor based switch with implemented diode characteristic may be obtained. The mentioned half bridge configuration may be used as such or alone or may be combined with one or more further half bridges (or other electric circuits) to realize a more complex electric function. For instance, two such half bridges may form a full bridge.

For instance, the two chips (which may be two IGBT or MOSFET or vertical transistor dies) can be identical or may be made at least by the same technology. However, the two chips may also have different electrical parameters. For instance, the two chips may be made by different front-end technologies and may be used in a single half bridge configuration. For example, the two chips may be made by the same chip technology and/or may have a similar internal structure. In particular, the two chips may be made by a similar internal chip technology where both chips present source and gate pad at one side and drain pad to the other side.

In the context of the present application, the term “main surface” of a body may particularly denote a largest body surface of one of the largest body surfaces. For instance, a body (such as a clip or a carrier or part thereof) may be plate-shaped or substantially plate-shaped and may then have two opposing main surfaces separated by body material in a thickness direction and connected with each other by a circumferential edge. For example, one main surface of a body may be at least partially exposed. Additionally or alternatively, one main surface (for instance another main surface) of a body may be connected to one or more chips.

In an embodiment, the first chip is a low-side chip, and the second chip is a high-side chip. Advantageously, the low-side chip may be arranged in a drain-down (or collector-down) configuration, whereas the high-side chip may be arranged in a source-down (or emitter-down) configuration. This design may promote the high electric performance and high reliability of the package.

In an embodiment, a surface portion of the chip carrier-type body facing away from the first chip and from the second chip forms an exposed exterior package surface. Thus, the exposed surface portion of the single integral electrically conductive body may contribute significantly to heat removal out of an interior of the package. Preferably, a leadframe part may be exposed and a clip part may be not exposed and buried in a mold compound. In one embodiment, only a leadframe part is exposed. In another embodiment, both a leadframe part and at least one of at least one clip may be at least partially exposed.

In the following, various embodiments relating to lead structures and connection elements for electrically connecting the various terminals will be explained. A corresponding lead structure may comprise one or a plurality of electrically conductive leads which may be accessible from an exterior of the package, for instance by being exposed beyond an encapsulant encapsulating part of the constituents of the package. A respective lead structure may be connected with an assigned one of the above-mentioned terminals of the transistor chips by a respective connection element. Such a connection element may comprise for example a clip, a bond wire or a bond ribbon. A clip may be a curved electrically conductive body accomplishing an electric connection with a high connection area to an upper main surface of a respective electronic component. Additionally or alternatively to such a clip, it is also possible to implement one or more other electrically conductive connection elements in the package, for instance a bond wire and/or a bond ribbon.

In an embodiment, the package comprises a third terminal lead structure connected with the third terminal by a third terminal connection element. Said third terminal connection element may extend partially or entirely above the single integral electrically conductive body on the chip mounting main surface thereof.

In an embodiment, the package comprises a sixth terminal lead structure connected with the sixth terminal by a sixth terminal connection element. Said sixth terminal connection element may extend partially or entirely below the single integral electrically conductive body. More specifically, a gate wire for the high-side die can be arranged under the die pad.

In an embodiment, at least part of one of the third terminal connection element and the sixth terminal connection element extends above one main surface of the body, and at least part of the other one of the third terminal connection element and the sixth terminal connection element extends below said main surface of the body. By the described geometrical arrangement of the first and sixth terminal connection elements, a proper gate or base connection of the flipped chip and the non-flipped chip may be achieved. In particular, the third terminal connection element and the sixth terminal connection element may face two different opposing main surfaces of the body.

In an embodiment, at least one of the third terminal connection element and the sixth terminal connection element comprises a bond wire with a loop height which does not exceed a thickness of the single integral electrically conductive body. Preferably, the loop height of the gate wire is not higher than the thickness of the die pad, to ensure that the bond wire is not exposed from the package. Thus, the loop height of the bond wire should not exceed the die pad thickness. For instance, the loop height may be smaller than 200 μm. For example, such a bond wire may have a circular cross-section or may be flat (for instance may be embodied as bond ribbon). By using bond wires for establishing gate or base connections, a compact package may be manufactured.

In an embodiment, the third terminal lead structure and the sixth terminal lead structure are arranged to face two opposing edges or two opposing corners of the body. For example, the single integral electrically conductive body may have a substantially rectangular shape, wherein the gate or base lead structures may extend adjacent to two opposing corners of the substantially rectangular carrier. With the described configuration, a sufficiently large distance between the transistor chips on the common carrier may be ensured. This may have a positive impact on the electric performance and thermal reliability of the package.

In an embodiment, the package comprises a fifth terminal lead structure connected with the fifth terminal by an electrically conductive fifth terminal connection element. In particular, the fifth terminal lead structure may provide a connection of a drain of the high-side transistor chip.

In an embodiment, the package comprises a second terminal lead structure connected with the second terminal by an electrically conductive terminal connection second element. Said second terminal lead structure may be arranged side-by-side with and along the same edge of the component carrier as the fifth terminal lead structure.

In an embodiment, at least one of the electrically conductive fifth terminal connection element and the electrically conductive second terminal connection element comprises a clip. In the context of the present application, the term “clip” may particularly denote a three-dimensionally curved connection element which comprises an electrically conductive material such as copper and is an integral body with sections to be connected to an assigned chip terminal and the respectively structure.

In an embodiment, the package comprises a common terminals lead structure connected with the first terminal and with the fourth terminal, wherein for example the common terminals lead structure is integrally formed with the body. The common terminals lead structure may be arranged along an edge of the component carrier opposing another edge thereof along which the above-mentioned terminal lead second structure and the above-mentioned the fifth terminal lead structure are arranged.

In an embodiment, the package comprises an encapsulant at least partially encapsulating the body, the first chip and the second chip. For instance, the body may be partially encapsulated by and partially exposed beyond the encapsulant, whereas the first and second chips may be entirely encapsulated without exterior exposure. In the context of the present application, the term “encapsulant” may particularly denote a material, structure or member surrounding at least part of the transistor chips and at least part of the common carrier to provide mechanical protection, and optionally electrical insulation and/or a contribution to heat removal during operation. In particular, said encapsulant may be predominantly or even entirely electrically insulating, for instance a mold compound. A mold compound may comprise a matrix of flowable and hardenable material and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel).

For example, it is possible that the encapsulant is embodied as a single encapsulation body which covers all the mentioned elements. Alternatively, it is possible to provide separate encapsulation bodies for the different chips.

In an embodiment, the encapsulant is selected from a group consisting of a mold compound, and a laminate. For the encapsulating by molding, a plastic material or a ceramic material may be used. The encapsulant may comprise an epoxy material. Filler particles (for instance SiO₂, Al₂O₃, Si₃N₄, BN, AlN, diamond, etc.), for instance for improving thermal conductivity, may be embedded in an epoxy-based matrix of the encapsulant.

In an embodiment, the encapsulant comprises an exterior creepage distance increasing groove arranged for increasing a creepage distance between the (in particular chip carrier-type) body and lead structures (in particular the fifth terminal lead structure and the second terminal lead structure) being spaced with respect to the body. For high voltage applications (for instance a voltage class in a range from 600 V to 2000 V, for instance 1200 V), creepage current flowing along an exterior surface of the package may create highly undesired parasitic electrically conductive paths which may involve issues. In order to reliably prevent such parasitic current paths extending along an exterior surface of the package, a creepage distance increasing groove may be formed at an exterior surface of the encapsulant. This may create a trench between, on the one hand, the above-mentioned second terminal lead structure and the above-mentioned fifth terminal lead structure and, on the other hand, an exposed surface of the common carrier. To put it shortly, the creepage distance increasing groove may render a parasitic creepage current path longer and more complex, thereby suppressing the risk of creepage current. Such a creepage distance increasing groove may extend the whole way between two opposing edges of the encapsulant for maximum safety against creepage current. For example, the creepage distance increasing groove may be formed by a corresponding shaping of mold tools or by correspondingly removing material of the encapsulant after the encapsulation process.

Advantageously, the afore-mentioned creepage distance increasing groove may be the only creepage distance increasing groove of the package. Hence, only a single creepage distance increasing groove may be sufficient for the entire package. This may simplify the manufacturing process of the package.

In an embodiment, a main surface of the body facing away from the first chip and the second chip is at least partially exposed beyond the encapsulant. This may promote dissipation of heat created by the transistor chips during operation of the package via a preferably metallic surface of the body. Such a metallic surface (in particular a copper or aluminum surface) has a high thermal conductivity, so that the described measure may render heat dissipation highly efficient.

In an embodiment, the package comprises a thermal interface material (TIM) on at least part of the exposed main surface of the body. A thermal interface material may be any material that is inserted between the exposed main surface of the body and a heat sink in order to enhance the thermal coupling between them for improving heat dissipation. Furthermore, a TIM may reduce the thermal boundary resistance between body and heat sink. Moreover, a TIM may tackle application requirements such as low thermal stress between materials of different thermal expansion coefficients, low elastic modulus, etc. For instance, a thermal paste, a thermal adhesive or a thermally conductive pad may be used as a thermal interface material.

In an embodiment, the package comprises an

electrically insulating foil on the thermal interface instance, such an electrically insulating foil material. For may be embodied as a Kapton sandwiching an electrically insulating foil between the exposed body and a heat sink, even an electrically conductive interface material may be used. This may increase the freedom of design and may allow to optimize the thermal performance. In other embodiments (for instance when using an electrically insulating thermal interface material), the electrically insulating foil may be omitted.

In an embodiment, the package comprises a heat sink on the thermal interface material or on the electrically insulating foil. It is also possible that the electrically insulating foil is attached to a main surface of the heat sink. The heat sink may be mounted on or above an exposed surface of the back side of the carrier. An appropriate heat sink may be a heat dissipation body, which may be made of a highly thermally conductive material such as copper or aluminum. For instance, such a heat sink may have a base body facing said exposed back side of the carrier and may have a plurality of cooling fins extending from the base body and in parallel to each another so as to remove the heat towards the environment.

It is also possible that the exposed carrier itself functions as heat sink for cooling purposes.

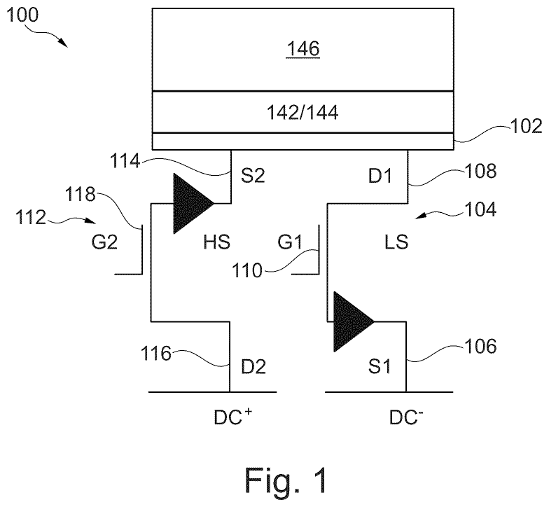

In an embodiment, the single integral electrically conductive body is a chip carrier. Such an embodiment is shown in FIG. 1 to FIG. 7. For example, the chip carrier may be a leadframe structure, a Direct Copper Bonding substrate, or a Direct Aluminum Bonding substrate. One common chip carrier is shared by both chips in such an embodiment. In another embodiment, the single integral

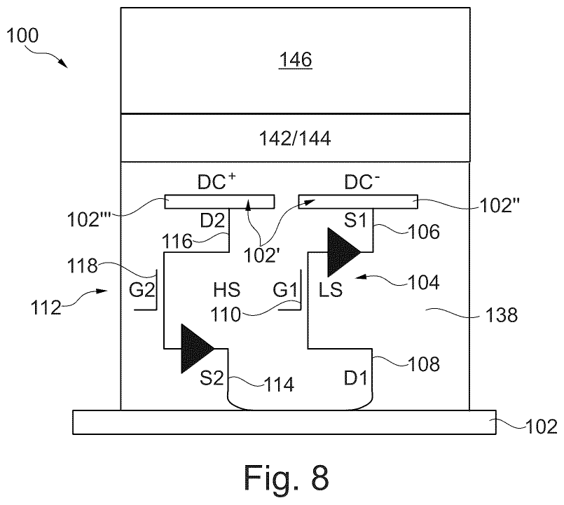

electrically conductive body is a common clip connected with both the first chip and the second chip. Such an embodiment is shown in FIG. 8 to FIG. 10. One common clip is shared by both chips in such an embodiment.

Still referring the to previously described embodiment, the package may additionally comprise a chip carrier on which the first chip and the second chip are mounted. Thus, one main surface of each of the chips may be mounted on the chip carrier, whereas an opposing other main surface of both chips may be connected to the common clip.

In an embodiment, the aforementioned chip carrier comprises a first die pad on which the first chip is mounted and comprises a second die pad on which the second chip is mounted and which is separate from the first die pad. Thus, split die pads may be foreseen at the chip carrier which may therefore be composed of separate bodies. Each chip may have an individually assigned die pad. However, both chips may share a common clip.

In an embodiment, the common clip is larger (for instance may have a larger main surface area) than each of the first die pad and the second die pad and does not contact the fifth terminal lead structure and the second terminal lead structure. Thus, the size of the big common clip may extend toward the DC+ (drain of high side die) and DC− (source of low side die), but does not touch the external drain lead of the high side die and the external source leads of the low side die. Such an embodiment is shown for example in FIG. 8 to FIG. 10.

In an embodiment, the package comprises an encapsulant at least partially encapsulating the body, the first chip and the second chip, and partially encapsulating the chip carrier so that at least part of one main surface of the chip carrier is exposed beyond the encapsulant. In particular, one respective main surface of each of the aforementioned split die pads of the chip carrier may be exposed. Such an exposed main surface may contribute to the removal of heat generated by the chips during operation of the package. The exposed main surfaces of the two die pads may be arranged side-by-side so as to be exposed as separated surfaces spaced by and exposed beyond the encapsulant.

In an embodiment, it may also be possible to expose a surface portion of the common clip-type body beyond the encapsulant. This may contribute additionally to a highly efficient heat removal and may thereby lead to a high thermal performance.

In an embodiment, the package comprises a thermal interface material (TIM) and/or an electrically insulating foil on at least part of the exposed main surface of the first die pad and the second die pad. The thermal interface material and/or the electrically insulating foil may be configured so as to be suitable for arranging a heat sink thereon.

In an embodiment, the single integral electrically conductive body faces away from the thermal interface material and/or from the electrically insulating foil. In contrast to this, the chip carrier (and in particular separate die pads thereof) may face the thermal interface material and/or the electrically insulating foil.

In an embodiment, the common clip is configured as a magnetic field suppressing element by allowing induced eddy currents to extend into the common clip. Advantageously, the extended clip structure may suppress detrimental magnetic field effects on the inductance. This clip extension does not contribute to the effective current path, but acts as a magnetic field suppressing element by allowing induced eddy currents to extend into. To put it shortly, a clip extension may be configured to act as magnetic field suppressor. Such a clip extension may be towards a DC+/DC− lead side. This can be a clip part where no current is directly flowing through, but which can take up parts of the electrical currents (i.e. eddy currents) which may be induced by the changing magnetic field produced by the current flowing through the die pads underneath. That architectural feature may suppress performance detrimental inductances further.

In an embodiment, there is no tie bar connected to the body. In an advantageous embodiment, no tie bar may extend to the exterior surface of the package. Thus, an outline of the package may be free of a tie bar. Tie bars may be used for interconnecting constituents of different packages during manufacture. In many cases, tie bars are made of metal, and may for example form part of a leadframe. During separating individual packages manufactured in a batch procedure, said tie bars may be separated as well. However, cutting through metallic tie bar material may be cumbersome and may decelerate the separation process. According to exemplary embodiments, tie bars may be omitted in particular in regions in which packages are singularized.

In an embodiment, the package is configured as tie bar-less package. In such an embodiment, the entire package may be entirely free of any tie bar. This may simplify the manufacturing process and may improve the electric reliability of the package, since no metallic tie bar material will then form part of the exterior surface of the package. The absence of tie bars at a package surface may improve electric reliability. Tie bar-less embodiments may be advantageous when high voltages are used.

However, embodiments without or with tie bars are possible. For example in a split die pad design, tie bars may be present to avoid significant mold flash due to a tilting die pad during molding. Here, methods such as retractable pins, vacuum mold tool, etc., may be advantageous.

In an embodiment, the first chip and the second chip are made by the same chip technology. It is even possible the first chip and the second chip are identical. In an embodiment, the first chip and the second chip have the same shape and dimension. In other words, the first chip and the second chip may be substantially identical semiconductor chips. When the two chips (providing the transistors) of the half bridge type package are identical in terms of shape, dimension and electric performance, it is sufficient to provide only one type of transistor chip for manufacturing the package. The advantage of this measure is simplicity. Using only one type of chips for providing the transistor functionality keeps the manufacturing effort of the package low.

Alternatively, the first chip and the second chip may have at least one of different shapes and different dimensions. Thus, it is also possible that the two chips have different sizes and/or different electric performance, for instance to take into account different duty cycles of the chips, or for enabling a separate optimization of a DC-DC functionality. For example in asymmetric half bridges, high-side and low side chips may have different sizes to allow a lower RDSON for the die which is longer in an ON state.

In an embodiment, at least one of the first chip and the second chip is configured for operation with a vertical current flow (in particular a current flow perpendicular to a plane within which the body extends). Chips being configured for a vertical current flow may have transistor terminals both at an upper main surface and a lower main surface, respectively, of the chip. In particular in such a vertical flow configuration, the package can be formed with extremely short current paths and thus with a quite simple layout.

In an embodiment, the chip carrier-type body comprises at least one of the group consisting of a leadframe structure, a Direct Copper Bonding substrate, and a Direct Aluminum Bonding substrate. In the context of the present application, the term “leadframe” may particularly denote a preferred example of a chip carrier-type body being configured as a sheet-like metallic structure which can be punched or patterned so as to form a leadframe body for mounting the chips. Connection leads for electric connection of the package to an electronic environment, when the chips are mounted on the leadframe, may be provided as well. In an embodiment, the leadframe may be a metal plate (in particular made of copper) which may be patterned, for instance by stamping or etching. Forming the chip carrier-type body as a leadframe is a cost-efficient and mechanically as well as electrically highly advantageous configuration in which a low ohmic connection of the chips can be combined with a robust support capability of the leadframe. Furthermore, a leadframe may contribute to the thermal conductivity of the package and may remove heat generated during operation of the chips as a result of the high thermal conductivity of the metallic (in particular copper) material of the leadframe. A DCB or DAB substrate has the advantage of a pronounced heat dissipation while electrically insulating an interior of the package with regard to an exterior thereof due to an electrically insulating and thermally conductive layer (for instance ceramic layer) between the two opposing electrically conductive layers (made of copper or aluminum).

In an embodiment, the gate wire of the high-side chip is below the main (or mounting) surface of the body, and the second surface (in particular the surface opposing the mounting surface) of the body may be exposed. Thus, the thickness of the body may limit the loop height of the gate wire of the high side chip. This may have an impact on the selection of the thickness of the body and the height loop of the gate wire of the high-side chip. Preferably, a minimal required mold thickness between loop top and mold body surface may be selected accordingly. This minimum thickness may depend on a filler material of the mold compound, but 150 μm may be a desirable choice. More generally, the thickness may be at least 200 μm, in particular at least 150 μm, and preferably at least 100 μm.

The described circuit architecture with the two chips and the body connected to form a half bridge can be realized with many different package types. More specifically, various different package architectures are compatible with the described connection architecture with compact layout and short electric paths. For instance, a PQFN package type is compatible with the described connection technology, as well as a HSOF package technology. In other embodiments, a Dual Sided Small Outline (DSO) package may be provided. Also a Quad Package (having pins on all four sides of the package) may be formed according to an exemplary embodiment. Therefore, the mentioned layout design can be easily adapted to various different package technologies.

In an embodiment, the chips with transistor are configured as power semiconductor chips. Thus, these chips (such as semiconductor chips) may be used for power applications for instance in the automotive field and may for instance have at least one integrated insulated-gate bipolar transistor (IGBT) and/or at least one transistor of another type (such as a MOSFET, a JFET, etc.). Such integrated circuit elements may be made for instance in silicon technology or based on wide-bandgap semiconductors (such as silicon carbide, gallium nitride or gallium nitride on silicon). A semiconductor power package may comprise inverter circuits, half bridges, full-bridges, drivers, logic circuits, etc.

As substrate or wafer forming the basis of the chips, a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages of the present invention will become apparent from the following description and the appended claims, taken in conjunction with the accompanying drawings, in which like parts or elements are denoted by like reference numbers.

Before describing further exemplary embodiments in further detail, some basic considerations will be summarized based on which exemplary embodiments have been developed.

In a conventional half bridge package, a split die pad may be implemented comprising two separate carrier sections each for mounting a respective transistor chip. A commutation loop routing may be external or internal, but may be in any case quite long. As a result, significant conductive losses may occur. Furthermore, such an approach may lead to a limited die pad size resulting in a corresponding ship size restriction. As a consequence, a thermal spreading and a thermal performance may be limited as well. Moreover, the limited die pad area may have a negative impact on the freedom of chip placement. Due to the limited thermal performance, a gap filler may be mandatory at a thermal interface.

According to an exemplary embodiment, a half bridge package is provided which has at least two correspondingly connected transistor chips (for instance embodied as field-effect transistor chips or bipolar transistor chips). The two transistor chips may be mounted on the same main surface of a common single integral electrically conductive body, such as a single common die pad. A drain-down (or collector-down) configuration of a first transistor chip is combined with a source-down (or emitter-down) configuration of the second transistor chip. Each of the first and second transistor chips may have its drain (or collector) terminal on one main surface, whereas the other terminals are arranged on the opposing other main surface of the respective transistor chip. As a consequence, the transistor chips may be operated with vertical current flow so that losses may be kept low, and the dimensions of the package may be limited. By assembling both transistor chips of the half bridge on a common unified die pad, one with a face-up and the other one with a face-down configuration, improvements concerning electric performance and thermal reliability may be achieved.

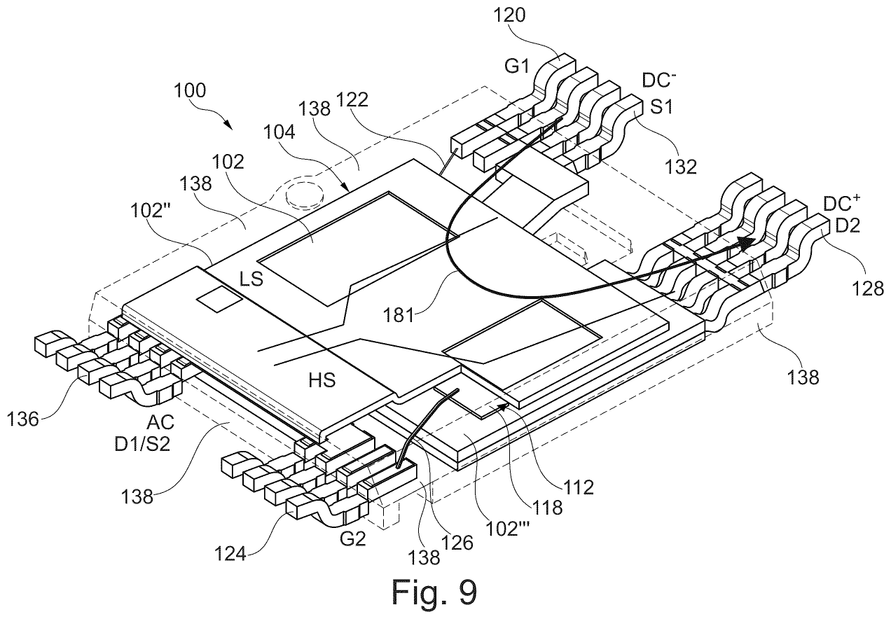

In particular, the described design allows to obtain a short commutation loop which may lead, in turn, to low inductive losses. A short commutation loop may be obtained due to a unified die pad directly connecting the drain of the low-side chip and the source of the high-side chip without an external connection outside the package via a mounting base such as a printed circuit board (PCB). According to an exemplary embodiment, a circuit design within the package may allow to close the DC−/DC+ (i.e. source of the low-side and drain of the high-side) loop with a very small loop diameter (as indicated for instance in FIG. 9) while still upholding crucial circuitry rules of a half bridge. In contrast to this, conventional half bridge designs may have a larger commutation loop that is closed via a PCB. Conventionally, this loop can only be shortened by a complicated PCB design.

A large continuous die pad area provided in common for both transistor chips may allow to freely and flexibly select appropriate chip-chip distances. This may reliably prevent overheating and may allow to obtain an appropriate electrical resistance characteristics (in particular in terms of R_{DS(on)} values). Consequently, a half bridge package with excellent electric performance and thermal reliability may be created.

In particular, an exemplary embodiment provides an integrated half bridge package with drain-down low-side transistor chip and source-down high-side transistor chip sharing a common single integral electrically conductive body. For example, a corresponding package may be embodied with QDPAK (Quadrupole DPAK) or PG-HDSOP-22 design. The single integral electrically conductive body may be embodied as a common die pad for both transistor chips. Such a design may provide a high (or even maximum) freedom of design concerning chip size and chip position within the package. These degrees of freedom may allow an improvement or even optimization of thermal performance (promoted by sufficiently large or even maximized chip distance) and electrical performance, in particular R_{DS(on)} performance (in view of reduced or even minimized wire lengths). Highly advantageously, a short or even minimal commutation loop may be achieved with such a design, which may lead to a reduction of inductive losses.

What concerns system integration, a cooler isolation foil may be provided to ensure to comply with a high voltage air distance criterion. Advantageously, an insulating, thermal interface material may be provided which may be embodied as a gap pad or gap filler. Such a thermal interface material may be configured to contribute to a low thermal resistance, as no additional insulation may be required.

In an embodiment, a mold groove may be formed in an encapsulant of the package. Such a mold groove may be adapted as an exterior creepage distance increasing groove which may extend a high voltage path from a high voltage lead to an exposed pad for complying with a high-voltage creepage criterion depending on the voltage class of a specific application. What concerns the high voltage lead, the critical potential may be on the leads connected to the drain of the high-side chip. It should also be mentioned that in a split die pad embodiment, a mold grove may be configured to provide enough creepage distance between the two pads.

Advantageously, an embodiment of the package may combine a high-side source-down assembly of one transistor chip with a low-side drain-down assembly of the other transistor chip on a single unified die pad. Such a unified die pad or single integral electrically conductive body in combination with one flip chip transistor chip and one non-flip chip transistor chip may provide an excellent power chip architecture for both the high-side and the low-side switch.

An interface to compensate height tolerances to a heat sink or cooler can be further improved for lowest thermal resistance. However, the heat sink or cooler may be insulated.

In particular for high voltage operation (for example at an operating voltage of more than 750 V), the provision of the above-described mold groove and/or a tie bar less design may be advantageous.

What concerns the first and second transistor chip, which may form a low-side switch and a high-side switch, respectively, they may be preferably embodied silicon carbide dies. In one embodiment, the first and second transistor chips may be identical dies or may differ concerning size and/or shape and/or performance. For example, the first and second transistor chips may be embodied as MOSFETs, IGBTs, CoolMOS™ chips, etc.

Advantageously, a respective clip may be used for accomplishing drain and/or source connection. Wire bonding may be used for gate connection.

In a preferred embodiment, a half bridge package is provided which has two dies attached to one common die pad. One of the dies is assembled with a source-down configuration (i.e. with its source pad directly attached to die pad) and the other die is assembled with a drain-down configuration (i.e. with its drain pad directly attached to die pad).

An additional advantageous feature is the provision of only one creepage distance increasing groove between an exposed surface of the die pad and those leads on one side of the body which correspond to the source and drain terminals facing away from the body. Further leads on the opposite side can be physically connected to the die pad.

In the following description of the figures, exemplary embodiments will be described for a field effect transistor having source, drain and gate terminals. However, a person skilled in the art will understand that these and other embodiments can also be constructed as a bipolar transistor having emitter (rather than source), collector (rather than drain) and base (rather than gate) terminals.

FIG. 1 shows a schematic circuit diagram of a package 100 with its interconnections according to an exemplary embodiment.

The package 100 according to FIG. 1 comprises a single integral electrically conductive chip carrier-type body 102, which can be embodied as a metallic leadframe structure. The single integral electrically conductive body 102 may be a structured electrically conductive plate-like body.

A first chip 104 is provided with an integrated field-effect transistor (or alternatively with an integrated bipolar transistor). First chip 104 may be a semiconductor chip, for instance manufactured in silicon carbide or gallium nitride technology (for instance implementing a vertical GaN chip architecture). The first chip 104 is assembled on the body 102, for instance by soldering or sintering.

A second chip 112 is provided with an integrated field-effect transistor (or alternatively with an integrated bipolar transistor). Second chip 112 may be a semiconductor chip, for instance manufactured in silicon carbide or gallium nitride technology. The second chip 112 is assembled on the same body 102 as the first chip 104, for instance by soldering or sintering.

In one embodiment, the first chip 104 and the second chip 112 may be identical chips, for instance chips from the same manufacturing lot. Thus, the first chip 104 and the second chip 112 may have the same shape and dimensions and may have the same material composition and electric characteristic. Alternatively, the first chip 104 and the second chip 112 may have different shape and/or dimension and/or material composition and/or electric characteristic. For example, such different properties of the chips 104, 112 may be in accordance with different duty cycles of the first chip 104 and the second chip 105 during operation of the package.

Each of the first chip 104 and the second chip 112 have a plurality of terminals or pads as their electric chip interfaces:

As shown, the first chip 104 comprises a first terminal 108 (being a drain terminal indicated as D1) which is attached on the body 102. For example, the first chip 104 may be soldered on the body 102 at its first terminal 108. Moreover, the first chip 104 comprises a second terminal 106 (being a source terminal indicated as S1) and a third terminal 110 (being a gate terminal indicated as G1). Although not shown in FIG. 1, the second terminal 106 and the third terminal 110 are formed on one common main surface of the first chip 104 which faces away from the body 102. In contrast to this, the first terminal 108 is formed on an opposing other main surface of the first chip 104 which faces the body 102. The first chip 104 may be configured to experience a vertical current flow between its opposing main surfaces during operation of the package 100. A control signal may be applied to the third terminal 110 to control operation of the first chip 104. As shown in FIG. 1, the second terminal 106 may be at a fixed electric potential, DC−, during operation of the package 100. A floating electric potential may be generated at the first terminal 108 during operation.

The second chip 112 comprises a fourth terminal 114 (being a further source terminal indicated as S2) which is attached on the body 102 so as to be electrically coupled with the first terminal 108. For example, the second chip 112 may be soldered on the body 102 at its fourth terminal 114. The fourth terminal 114 may be located on the electrically conductive body 102 side-by-side with the first terminal 108. Thus, the fourth terminal 114 and the first terminal 108 may be at the same floating electric potential during operation of the package 100. Moreover, the second chip 112 comprises a fifth terminal 116 (being a further drain terminal indicated as D2) and a sixth terminal 118 (being a further gate terminal indicated as G2). Although not shown in FIG. 1, the fourth terminal 114 and the sixth terminal 118 are formed on one main surface of the second chip 112 facing the body 102. In contrast to this, the fifth terminal 116 is formed on an opposing other main surface of the second chip 112 facing away from the body 102. Also the second chip 112 may experience a vertical current flow between its opposing main surfaces during operation of the package 100. A control signal may be applied to the sixth terminal 118 to control operation of the second chip 112. As shown in FIG. 1, the fifth terminal 116 is at a fixed electric potential, DC+, during operation of the package 100. A floating electric potential may be generated at the fourth terminal 114 during operation.

Thus, control signals may be applied to the gate terminals 110, 118 during operation of the package 100. Fixed electric potentials DC− and DC+ may be applied to the second terminal 106 and the fifth terminal 116, respectively. As a result, switch signals may be created at first terminal 108 and fourth terminal 114.

In view of the described interconnection, the first chip 104 and the second chip 112 are connected to form a half bridge. In the context of said half bridge functionality, the first chip 104 is a low-side chip (indicated as LS) and the second chip 112 is a high-side chip (indicated as HS). The electric circuitry formed by the interconnected first chip 104 and second chip 112 corresponds to circuit diagram 152 of FIG. 4.

Still referring to FIG. 1, a main surface of the body 102 facing away from the first chip 104 and from the second chip 112 may be, partially or entirely, exposed. A thermal interface material (TIM) 142 may be formed on the exposed main surface of the body 102. The thermal interface material 142 may for instance be a thermal paste providing a thermal coupling with a heat sink 146 with low thermal resistance in between. For instance, the thermal interface material 142 may be electrically insulating for additionally providing a dielectric protection of the exposed body 102. The thermal interface material 142 may contribute to the dissipation of heat from an interior of the package 100, wherein said heat may be generated predominantly by the first chip 104 and the second chip 112. Moreover, the thermal interface material 142 may contribute to electric safety.

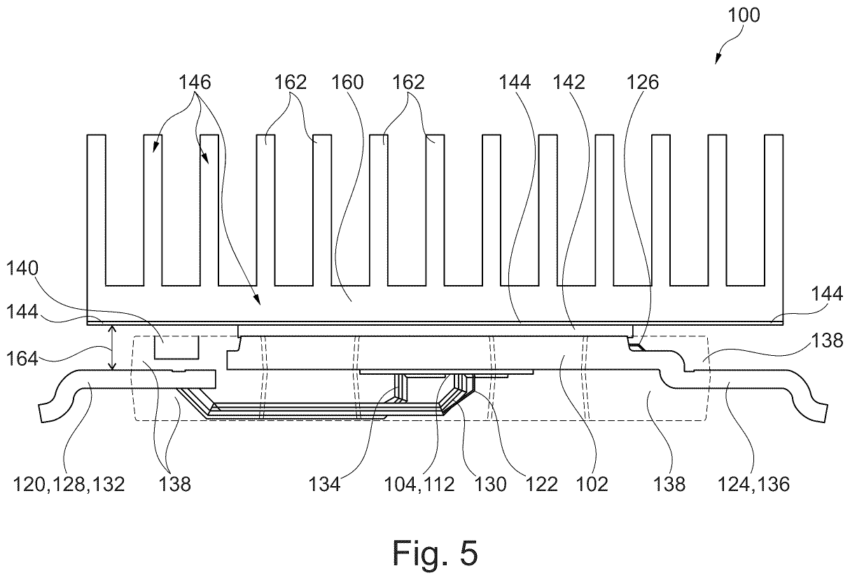

However, it may also be possible that the thermal interface material 142 is electrically conductive, for instance for providing excellent thermal conductivity and for cost-reduction purposes. For example in such a case, the package 100 may additionally comprise an electrically insulating foil 144 between the thermal interface material 142 and the heat sink 146 (compare for example FIG. 5). In such a scenario, the electrically insulating foil 144 may ensure electric isolation of the exposed electrically conductive body 102 and may therefore add an electric safety feature.

The already mentioned heat sink 146 on the thermal interface material 142 or on the electrically insulating foil 144 may receive the heat conducted away from the chips 104, 112, i.e. from the actual heat sources, and may dissipate the heat to the environment. For example, the heat sink 146 may have cooling fins for air cooling or may be a liquid cooler (for instance may be a water cooler).

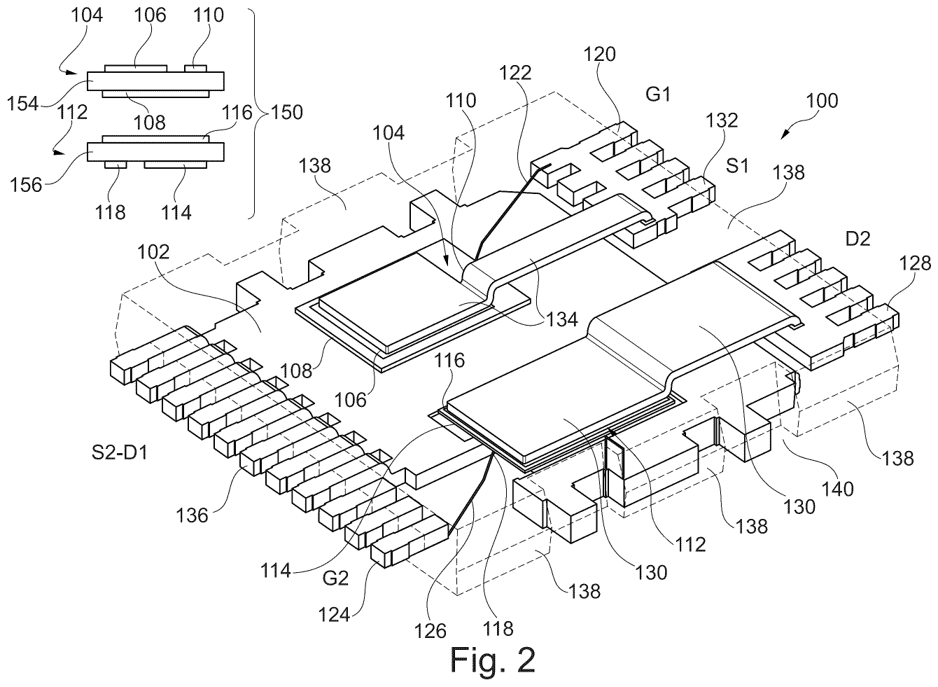

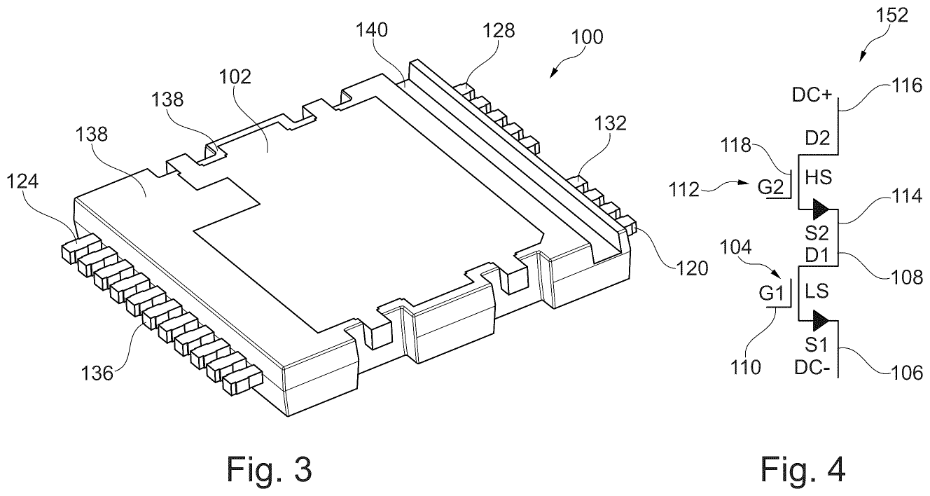

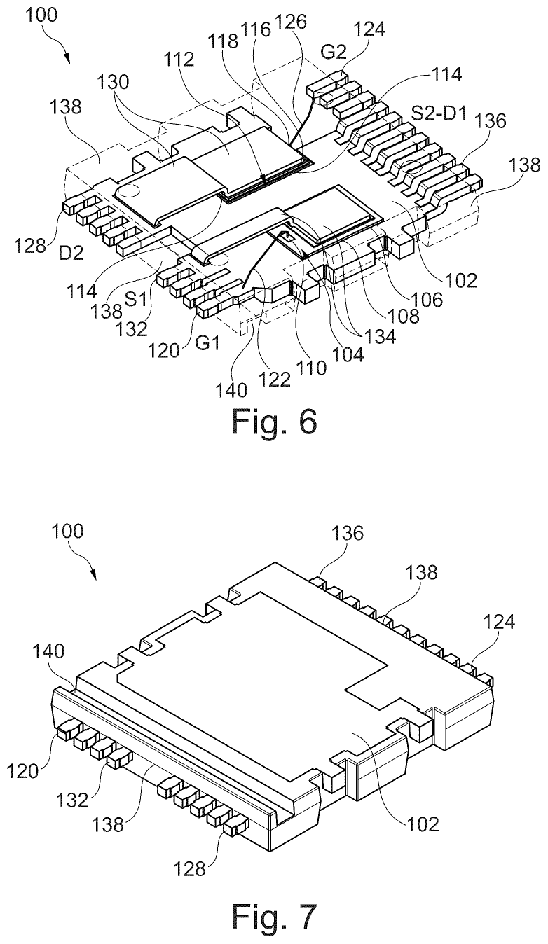

FIG. 2 shows a three-dimensional transparent view of a package 100 according to an exemplary embodiment. In particular, an outline of an encapsulant 138 is shown which encapsulates various constituents of package 100. However, said encapsulated constituents of package 100 are illustrated in FIG. 2 as well. Schematic side views 150 of chips 104, 112 are shown as well in FIG. 2. FIG. 3 shows a three-dimensional view of an outline of the package 100 according to FIG. 2, in which constituents of package 100 covered by material of the encapsulant 138 or of chip carrier-type body 102 are not visible. FIG. 4 shows a circuit diagram 152 of the half bridge-type package 100 according to FIG. 2 (said circuit diagram 152 representing also the circuitry of the schematic illustration of FIG. 1). FIG. 5 shows a cross-sectional view of the package 100 according to FIG. 2, wherein additional constituents (thermal interface material 142, electrically insulating foil 144, heat sink 146) are shown as well. FIG. 6 shows another three-dimensional transparent view of the package 100 according to FIG. 2 from another viewing direction (however, there may be minor differences between FIG. 6 and FIG. 2 what concerns the detailed design of leads, die pad, gaps, etc.). FIG. 7 shows another three-dimensional outline view of the package 100 according to FIG. 2 from another viewing direction than in FIG. 3.

Now referring to FIG. 2 to FIG. 7 in further detail, the illustrated power semiconductor package 100 with half bridge functionality comprises a single integral electrically conductive chip carrier-type body 102 embodied as unified die pad. For instance, the single integral electrically conductive body 102 may be a single continuous leadframe body made for instance of highly electrically and thermally conductive material, such as copper. The single integral electrically conductive body 102 serves as a common mounting base for a first chip 104 and a second chip 112. The first chip 104 and the second chip 112 are located side-by-side on the same main surface of the body 102. More precisely, the first chip 104 is arranged completely on the body 102. In contrast to this, only part of the second chip 112 is arranged on the body 102. More specifically, a part of the second chip 112 corresponding to below described fourth terminal 114 is arranged on the body 102. However, another part of the second chip 112 corresponding to below described sixth terminal 118 extends laterally beyond the body 102 (for instance in an overhanging manner) so as to be electrically connectable (for instance with an electrically conductive gate connection element 126, as described below). Thus, the sixth terminal 118 of the second chip 112 extends laterally beyond the body 102 so as to be exposed with respect to the body 102.

As shown in FIG. 2, there may be no tie bars connected to the body 102. Thus, package 100 may be configured as a tie bar-less package, which may be advantageous for high-voltage applications. In other embodiments, one or more tie bars may be present.

Tie bar less designs may be realized by a mold strategy to avoid larger mold flashes on the exposed die pad areas. A retractable pin strategy may be used where some pins protruding from the mold tool are placed on the die pads from the side where the chips are mounted thereby pressing down the die pads during the influx of the mold material (such as an epoxy mold compound, EMC). Once no large shear pressure on the die pads by the influx of EMC is to be expected, the pins retract thereby allowing some EMC to fill the place of the pins in the final part of the mold process.

The first chip 104 may be a power semiconductor transistor chip which may comprise a monolithically integrated MOSFET (or alternatively an IGBT, not shown). More specifically, the transistor of first chip 104 may be monolithically integrated in a semiconductor body 154, for instance comprising silicon or silicon carbide. A first terminal 108 of the first chip 104 is formed on a bottom main surface of first chip 104 and is attached on and connected with the body 102, for example by soldering. A second terminal 106 and a third terminal 110 are formed side-by-side on an upper main surface of first chip 104. Hence, first chip 104 is embodied as a device for a vertical current flow (for instance a current flow in a vertical direction according to FIG. 5).

Also the second chip 112 may be a power semiconductor transistor chip which may comprise a monolithically integrated MOSFET (or alternatively an IGBT, not shown). More specifically, the transistor of second chip 112 may be monolithically integrated in a semiconductor body 156, for instance comprising silicon or silicon carbide. A fourth terminal 114 of the second chip 112 is formed on a bottom main surface of second chip 112 and is attached on and connected with the body 102, for example by soldering. The fourth terminal 114 and a sixth terminal 118 of the second chip 112 are formed side-by-side on the bottom main surface of second chip 112, wherein the sixth terminal 118 has no direct physical connection with the body 102 in the shown embodiment. A fifth terminal 116 is formed on an opposing upper main surface of the second chip 112. Hence, also the second chip 112 is embodied as a device for a vertical current flow (for instance a current flow in a vertical direction according to FIG. 5).

Referring also to FIG. 4, the first chip 104 and the second chip 112 are interconnected to form a half bridge. In the framework of said half bridge configuration, the first chip 104 functions as a low-side chip, whereas the second chip 112 functions as a high-side chip.

Next, the interconnection of the various terminals of the chips 104, 112 will be explained in further detail:

As shown for instance in FIG. 2, a third terminal lead structure 120 is electrically connected with the third terminal 110 by a third terminal connection element 122. After encapsulation by a mold-type encapsulant 138, the third terminal lead structure 120 will extend partially beyond the encapsulant 138 to enable an electric coupling with an electronic periphery of package 100. In the illustrated embodiment, the third terminal connection element 122 may be a bond wire extending between the third terminal 110 and the third terminal lead structure 120. As shown in FIG. 2, said bond wire may extend above or may protrude beyond the chip mounting surface of the body 102.

Moreover, package 100 comprises a second gate lead structure 124 being electrically connected with the sixth terminal 118 by a second electrically conductive gate connection element 126. In the illustrated embodiment, the second electrically conductive gate connection element 126 may be a further bond wire extending between the sixth terminal 118 and the second gate lead structure 124.

Hence, referring to FIG. 2, the third terminal connection element 122 and the second electrically conductive gate connection element 126 extend beyond opposing main surfaces of the body 102. More specifically, the third terminal connection element 122 extends from the third terminal 110 on the upper main surface of the first chip 104, extends over and along the chip mounting surface of the body 102, and is then connected with the third terminal lead structure 120. In contrast to this, the second electrically conductive gate connection element 126 extends from the overhanging sixth terminal 118 on the lower main surface of the second chip 112, extends over and along the heat dissipation surface of the body 102, and is then connected with the second gate lead structure 124. Thus, one of the third terminal connection element 122 and the second electrically conductive gate connection element 126 extends above and the other below the body 102. Moreover, the third terminal lead structure 120 and the second gate lead structure 124 are arranged to face two opposing edges of the body 102.

In addition, package 100 comprises a drain lead structure 128 which is electrically connected with the fifth terminal 116 by a clip-type electrically conductive fifth terminal connection element 130. The clip constituting electrically conductive fifth terminal connection element 130 bridges a vertical gap between the upper main surface of the second chip 112 and the upper main surface of the drain lead structure 128. In the illustrated embodiment, fifth terminal connection element 130 is a clip, connecting the D2 pad of the high-side chip 112 to the D2 leads of the package 100, wherein the D2 leads and the clip are two separate metal pieces.

Furthermore, package 100 comprises a source lead structure 132 connected with the second terminal 106 by a further clip-type electrically conductive source connection element 134. The further clip constituting electrically conductive source connection element 134 bridges a vertical gap between the upper main surface of the first chip 104 and the upper main surface of the source lead structure 132.

As shown, the third terminal lead structure 120, the source lead structure 132, and the drain lead structure 128 are laterally spaced from each other and are arranged side-by-side along the same edge of the body 102.

In addition, package 100 comprises a common source-drain lead structure 136 being electrically connected with the first terminal 108 on the bottom side of first chip 104 and with the fourth terminal 114 on the bottom side of second chip 112. The common source-drain lead structure 128 may be integrally formed with the body 102, i.e. may form part of the single integral electrically conductive body 102. In the shown embodiment, a common piece of metal functions as a die pad for D1 and S2, and physically connects to common source-drain lead structure 136 as a whole piece of metal.

As shown, the second gate lead structure 124 and the common source-drain lead structure 136 are laterally spaced from each other and are arranged side-by-side along the same edge of the body 102.

As already mentioned, package 100 comprises an encapsulant 138 which partially encapsulates the body 102 and which fully encapsulates the first chip 104 and the second chip 112. The encapsulant 138 may be a mold-type encapsulant with filler particles for enhancing thermal conductivity. The encapsulant 138 is electrically insulating and provides mechanical protection.

As best seen in FIG. 3 and FIG. 7, a surface portion of the body 102 facing away from the first chip 104 and from the second chip 112, i.e. the above-mentioned heat dissipation surface, forms an exposed exterior package surface.

Now referring to FIG. 5, a thermal interface material (TIM) 142 may be formed on the exposed main surface of the body 102. For instance, the thermal interface material 142 may be embodied as a gap pad or thermal grease. For example, the thermal interface material 142 may enhance thermal conductivity and may balance out height tolerances of dimensions. A vertical thickness of the thermal interface material 142 may be for example in a range from 200 um to 1000 μm, for instance 500 μm. In one embodiment, the thermal interface material 142 may be electrically insulating and may therefore also provide a dielectric protection of the exposed metallic surface of the body 102. In another embodiment, the thermal interface 142 material may be electrically conductive, thereby further increasing thermal conductivity. Furthermore, an electrically conductive thermal interface material 142 may be cheaper than an electrically insulating one.

As shown as well in FIG. 5, the package 100 may further comprise an electrically insulating foil 144 which may function as cooler isolation on the thermal interface material 142. For instance, electrically insulating foil 144 may be a Kapton tape. A vertical thickness of the electrically insulating foil 144 may be for example in a range from 50 μm to 200 μm, for instance 70 μm. When the thermal interface material 142 is electrically insulating, the electrically insulating foil 144 is optional. When the thermal interface material 142 is electrically conductive, the electrically insulating foil 144 is of particular advantage, since it may then ensure electrical isolation.

Still referring to FIG. 5, the package 100 may comprise a heat sink 146 arranged on the electrically insulating foil 144 which may be arranged, in turn, on the thermal interface material 142. For example, the heat sink 146 may comprise a thermally conductive plate 160 from which a plurality of cooling fins 162, also made of a thermally conductive material, extend upwardly. Preferably, heat sink 146 may be made of a metal or a ceramic to provide a high thermal conductivity. Heat generated by the chips 104, 112 may be dissipated via the body 102, the thermal interface material 142, optionally the electrically insulating foil 144 and the heat sink 146 to an environment, for instance by air cooling.

As shown in FIG. 5, the electrically insulating foil 144 may be also arranged on the heat sink 146 where the latter faces package 100. leads of The electrically insulating foil 144 on heat sink 146 is vertically spaced from the leads by a high voltage distance gap 164. This contributes to high voltage compatibility (for instance up to at least 1200 V).

Yet another advantageous feature of package 100 is an exterior creepage distance increasing groove 140, as best seen in FIG. 3 and FIG. 7. The creepage distance increasing groove 140 can be formed as an exterior indentation in encapsulant 138 extending along the full distance between opposing edges of encapsulant 138. Advantageously, the creepage distance increasing groove 140 may be arranged for increasing a creepage distance between, on the one hand, the exposed cooling surface of the body 102 and, on the other hand, the drain lead structure 128 and the source lead structure 132. The latter lead structures 128, 132 are spaced with respect to the body 102 by material of encapsulant 138, and the creepage distance increasing groove 140 is formed in this spacing region. For instance by humidity in an environment, a parasitic electrically conductive path may be created unintentionally between the exposed surface of the electrically conductive body 102 and the lead structures 120, 128, 132. By forming the creepage distance increasing groove 140 in between, the length of the parasitic creepage path may be extended and the complexity of the parasitic creepage path may be enhanced. Thus, the creepage distance increasing groove 140 may improve the electric reliability of the package 100. Hence, the creepage distance increasing groove 140 may improve electric isolation and may render package 100 suitable for high-voltage applications.

In one embodiment, creepage distance increasing groove 140 may be at least partially filled with a gap filler material, for instance a thermal grease.

Advantageously, the illustrated package 100 has a shorter commutation path than in conventional package designs. This may improve the stray inductance properties and may lead to lower inductive losses. Furthermore, the large die area of the single integral electrically conductive body 100 of the embodiment of FIG. 2 to FIG. 7 improves the performance of package 100.

For example, half bridge packages 100 according to FIG. 1 to FIG. 7 may be used for a circuit of a three-phase motor control. For each phase of a motor, a package 100 with half bridge configuration, composed of a high-side transistor chip 112 between a supply voltage and phase and a low-side transistor chip 104 between phase and ground may be implemented. For example, a three-phase motor bridge may implement three high-side transistor chips 112 connected to a battery and three low-side transistor chips 104 connected to ground. Of course, many other applications are possible with half bridge packages 100. Thus, an electronic device may be provided which comprises a plurality of packages 100. Such an electronic device may form for instance a circuit of a motor control, for example a three-phase motor control.

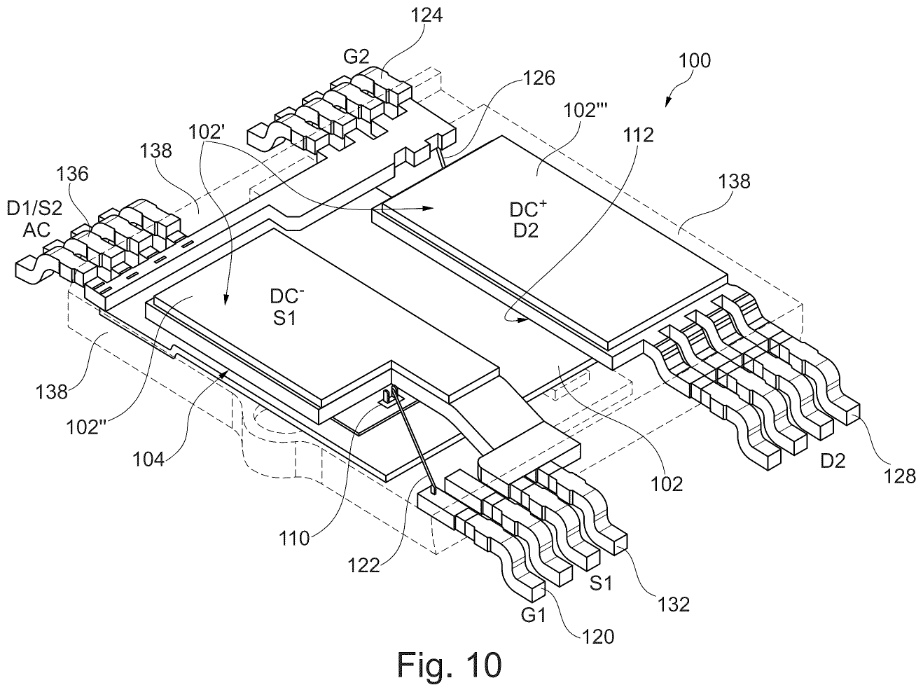

FIG. 8 shows a schematic circuit diagram of a package 100 with its interconnections according to another exemplary embodiment. FIG. 9 shows a three-dimensional transparent view of a package 100 according to the exemplary embodiment of FIG. 8. In particular, an outline of an encapsulant 138 is shown which encapsulates various constituents of package 100. However, said encapsulated constituents of package 100 are illustrated in FIG. 9 as well. FIG. 10 shows another three-dimensional transparent view of the package 100 according to FIG. 9.

In the following, mainly the differences between the embodiments of FIG. 1 to FIG. 7 and the embodiment of FIG. 8 to FIG. 10 will be explained. Apart from these differences, reference is made to the corresponding description above.

According to FIG. 8 to FIG. 10, the single integral electrically conductive body 102 is a common clip (rather than a common chip carrier, as in FIG. 1 to FIG. 7) and is connected with both the first chip 104 and the second chip 112. More specifically, the first terminal 108 (which is a drain terminal) is directly connected with the common clip-type single integral electrically conductive body 102. Moreover, the fourth terminal 114 (which is a source terminal) of the second chip 112 is directly connected with the same main surface of the common clip-type single integral electrically conductive body 102 as the first terminal 108 of the first chip 104.

In addition to the common clip-type single integral electrically conductive body 102, the embodiment of FIG. 8 to FIG. 10 comprises a leadframe-type chip carrier 102′ on which the other main surfaces of the first chip 104 and the second chip 112 are mounted. More specifically, the chip carrier 102′ comprises a first die pad 102″ on which the first chip 104 is mounted and comprises a second die pad 102′″ on which the second chip 112 is mounted. Contrary to the embodiments of FIG. 1 to FIG. 7, the chip carrier 102′ of the embodiment of FIG. 8 to FIG. 10 is not a single integral body, but in contrast to this comprises a first body in form of the first die pad 102′ and a separate second body forming the second die pad 102′″.

An encapsulant 138, such as a mold compound, may encapsulate the common clip-type body 102, the first chip 104 and the second chip 112. Moreover, encapsulant 138 may only partially encapsulate the chip carrier 102′ in such a way that one main surface of the first die pad 102″ and one main surface of the second die pad 102′″ are exposed beyond the encapsulant 138. The exposed main surfaces of the first die pad 102″ and of the second die pad 102′″ may oppose a respectively other main surface of the first die pad 102″ and of the second die pad 102′″ being connected to the chips 104, 112. Optionally, also a surface portion of body 102 may be exposed beyond the encapsulant 138. Said exposed main surfaces may contribute to removal of heat generated by the chips 104, 112 during operation of package 100.

For efficiently removing heat and simultaneously ensuring electric isolation (and consequently electric reliability) of package 100, a thermal interface material 142 and/or an electrically insulating foil 144 may be arranged on the exposed main surfaces of the first die pad 102″ and the second die pad 102′″. A heat sink 146 may be arranged on the thermal interface material 142 and/or the electrically insulating foil 144 for enhancing the heat removal capability of package 100. As shown, the single integral electrically conductive body 102 faces away from the thermal interface material 142 and from the electrically insulating foil 144.

As best seen in FIG. 10, the die pad 102″ physically connects the D2 pad with the D2 leads (see reference sign 128) as a single integral metal structure.

In FIG. 8 to FIG. 10, clip-type body 102 may be attached to the leads according to reference sign 136, for example by soldering, glue, etc., so that two different metal pieces may be present.

The embodiment of FIG. 8 to FIG. 10 provides an improved loop inductance for the illustrated integrated half bridge package 100. What concerns loop inductance, the DC loop may be reduced significantly according to FIG. 8 to FIG. 10 in comparison with conventional approaches. In particular, it may be beneficial that a spatial clip extension may be obtained along the DC path to suppress performance detrimental magnetic fields (so as to obtain advantageous properties in terms of eddy currents).

According to FIG. 8 to FIG. 10, a common single clip is provided as single common electrically conductive body 102. This may lead to a full switch node potential collection from the high-side second chip 112 and the low-side first chip 104. Advantageously, only DC potentials are present on exposed pads. Moreover, the illustrated clip design ensures a high ampacity. Furthermore, the clip extension may suppress magnetic fields which may be detrimental in terms of performance. Advantageously, the clip extension does not contribute to the effective current path, but acts as a magnetic field suppressing element by allowing induced eddy currents to extend into. Apart from this, the shown design may lead to a small commutation loop, as illustrated by reference sign 181 in FIG. 9.

Thus, an integrated half-bridge package 100 with improved electrical performance can be obtained. Consequently, ease of package handling on a user side can be accomplished.

Especially for silicon carbide technologies, the improvements in electrical performance are significant. In particular, the package design according to FIG. 8 to FIG. 10 may allow to pair a high current density with a low package inductance. Advantageously, package 100 may allow to reduce or even minimize an electrical figure of merits, such as loop inductance.

To put it shortly, the embodiment of FIG. 8 to FIG. 10 provides an integrated semiconductor package 100 in half-bridge configuration with one power chip assembled face-up and one power chip assembled face-down. Advantageously, the switch node potential (illustrated in FIG. 8 to FIG. 10 as D1/S2 or AC, for alternating current) of both power chips 104, 112 is interconnected directly to the clip-type single integral electrically conductive body 102. Advantageously, the embodiment of FIG. 8 to FIG. 10 relies on a power interconnect technology which can be a single clip architecture.

In other configurations (not shown), a suitable power interconnect technology may be the use of multiple clips (including clip-on-clip interconnect), or wire-bonded interconnects (chip-to-chip and chip-to-substrate), or a combination of clip-type and wire bonded interconnects (for example one clip for each chip and one wire to connect them)).

Advantageously, the clip structure forming body 102 in FIG. 8 to FIG. 10 extends over the die dimensions in the direction where it is not electrically connected, to form an eddy-current plate.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, comprising:
a single integral electrically conductive body;
a first chip with an integrated transistor and comprising a first terminal attached on the body, a second terminal, and a third terminal, wherein the second terminal and the third terminal are formed on one main surface of the first chip and the first terminal is formed on an opposing other main surface of the first chip, wherein the first terminal is a drain or collector terminal, the second terminal is a source or emitter terminal, and the third terminal is a gate or base terminal;
a second chip with an integrated transistor and comprising a fourth terminal attached on the body, a fifth terminal and a sixth terminal, wherein the fourth terminal and the sixth terminal are formed on one main surface of the second chip and the fifth terminal is formed on an opposing other main surface of the second chip, wherein the fourth terminal is a source or emitter terminal, the fifth terminal is a drain or collector terminal, and the sixth terminal is a gate or base terminal;
a third terminal lead structure connected with the third terminal by a third terminal connection element; and
a sixth terminal lead structure connected with the sixth terminal by a sixth terminal connection element,
wherein the first chip and the second chip are connected to form a half bridge, and
wherein at least part of one of the third terminal connection element and the sixth terminal connection element extends above one main surface of the body, and at least part of the other one of the third terminal connection element and the sixth terminal connection element extends below said main surface of the body.

2. The package according to claim 1, wherein the first chip is a low-side chip and the second chip is a high-side chip.

3. The package according to claim 1, wherein a surface portion of the body facing away from the first chip and from the second chip forms an exposed exterior package surface.

4. The package according to claim 1, wherein at least one of the third terminal connection element and the sixth terminal connection element comprises a bond wire with a loop height which does not exceed a thickness of the single integral electrically conductive body, wherein in particular the third terminal lead structure and the sixth terminal lead structure are arranged to face two opposing edges of the body.

5. The package according to claim 1, comprising a fifth terminal lead structure connected with the fifth terminal by an electrically conductive fifth terminal connection element.

6. The package according to claim 1, comprising a second terminal lead structure connected with the second terminal by an electrically second conductive terminal connection element.

7. The package according to claim 6, wherein at least one of the electrically conductive fifth terminal connection element and the electrically conductive second terminal connection element comprises a clip.

8. The package according to claim 1, comprising a common terminals lead structure connected with the first terminal and with the fourth terminal, wherein for example the common terminals lead structure is integrally formed with the body.

9. The package according to claim 1, comprising an encapsulant at least partially encapsulating the body, the first chip and the second chip.

10. The package according to claim 9, wherein the encapsulant comprises an exterior creepage distance increasing groove arranged for increasing a creepage distance between the body and lead structures, e a fifth terminal lead structure connected with the fifth terminal and a second terminal lead structure connected with the second terminal, being spaced with respect to the body.

11. The package according to claim 10, wherein a main surface of the body facing away from the first chip and the second chip is at least partially exposed beyond the encapsulant.

12. The package according to claim 11, comprising a thermal interface material on at least part of the exposed main surface of the body.

13. The package according to claim 12, comprising at least one of the following features:
the package comprising an electrically insulating foil on the thermal interface material;
the package comprising a heat sink on the thermal interface material or on the electrically insulating foil.

14. The package according to claim 1, wherein the single integral electrically conductive body is a chip carrier, for example at least one of the group consisting of a leadframe structure, a Direct Copper Bonding substrate, and a Direct Aluminum Bonding substrate.

15. The package according to claim 1, wherein the single integral electrically conductive body is a common clip connected with both the first chip and the second chip.

16. The package according to claim 15, comprising a chip carrier on which the first chip and the second chip are mounted.

17. The package according to claim 16, wherein the chip carrier comprises a first die pad on which the first chip is mounted and comprises a second die pad on which the second chip is mounted and which is separate from the first die pad.

18. The package according to claim 17, wherein the common clip is larger than each of the first die pad and the second die pad and does not contact the fifth terminal lead structure and the second terminal lead structure.

19. The package according to claim 16, comprising an encapsulant at least partially encapsulating the body, the first chip and the second chip, and partially encapsulating the chip carrier so that at least part of one main surface of the chip carrier is exposed beyond the encapsulant.

20. The package according to claim 16, comprising a thermal interface material and/or an electrically insulating foil on at least part of the exposed main surface of the first die pad and the second die pad for arranging a heat sink on the thermal interface material and/or the electrically insulating foil.

21. The package according to claim 20, wherein the single integral electrically conductive body faces away from the thermal interface material and/or from the electrically insulating foil.

22. The package according to claim 15, wherein the common clip is configured as a magnetic field suppressing element by allowing induced eddy currents to extend into the common clip.

23. The package according to claim 1, comprising at least one of the following features:
wherein there is no tie bar connected to the body;
wherein the sixth terminal of the second chip extends laterally beyond the body so as to be exposed with respect to the body;
wherein the first chip and the second chip are made by the same chip technology;
wherein at least one of the first chip and the second chip is configured for operation with a vertical current flow.

24. A method of manufacturing a package, the method comprising:
mounting a first chip, which has an integrated transistor comprising a first terminal, a second terminal, and a third terminal, on a single integral electrically conductive body so that the first terminal is attached on the body, wherein the second terminal and the third terminal are formed on one main surface of the first chip and the first terminal is formed on an opposing other main surface of the first chip, wherein the first terminal is a drain or collector terminal, the second terminal is a source or emitter terminal, and the third terminal is a gate or base terminal;
mounting a second chip, which has an integrated transistor comprising a fourth terminal, a fifth terminal and a sixth terminal, on the body so that the fourth terminal is attached on the body, wherein the fourth terminal and the sixth terminal are formed on one main surface of the second chip and the fifth terminal is formed on an opposing other main surface of the second chip, wherein the fourth terminal is a source or emitter terminal, the fifth terminal is a drain or collector terminal, and the sixth terminal is a gate or base terminal;
connecting the first chip and the second chip to form a half bridge;
connecting a third terminal lead structure with the third terminal by a third terminal connection element; and
connecting a sixth terminal lead structure with the sixth terminal by a sixth terminal connection element,
wherein the first chip and the second chip are connected to form a half bridge, and
wherein at least part of one of the third terminal connection element and the sixth terminal connection element extends above one main surface of the body, and at least part of the other one of the third terminal connection element and the sixth terminal connection element extends below said main surface of the body.
